(19) United States
(12) Patent Application Publication
(10) Pub. No.: US 2013/0087359 A1
(43) Pub. Date: Apr. 11, 2013

(54) SUPER REPELLANT COATED GASKET FOR SAFETY SWITCH ENCLOSURE

(71) Applicants: Richard James LESLIE, New Baltimore, MI (US); Alaa Abdel-Azim ELMOURSI, Troy, MI (US); Randal D. GAZDECKI, Cleveland, TN (US)

(72) Inventors: Richard James LESLIE, New Baltimore, MI (US); Alaa Abdel-Azim ELMOURSI, Troy, MI (US); Randal D. GAZDECKI, Cleveland, TN (US)

(73) Assignee: EATON CORPORATION, Cleveland, OH (US)

(21) Appl. No.: 13/270,427

(22) Filed: Oct. 11, 2011

(51) Int. Cl. H05K 5/06; E06B 7/22; H05K 5/00

(52) U.S. Cl. 174/50.5; 174/520; 49/475.1

(57) ABSTRACT

A super repellant coated gasket is configured for installation on an enclosure that houses at least one safety switch. The coating may be hydrophobic, superhydrophobic, or oleophobic.

### BACKGROUND

Safety switches are used to provide a point of local electrical disconnect in a specific NEMA environment, such as food processing. Safety switches are provided so that an end load can be maintained, repaired, or replaced safely down circuit when power to the end load is disconnected by a locked-off switch. Many industries require that the safety switch be located “in-sight” of operators of the equipment protected by the safety switch. This means that the safety switch is regularly exposed to materials being processed as well as disinfectants used to clean the equipment. The primary purpose of the safety switch is to provide a local on-off switch that has a long life span in a corrosive environment (e.g., NEMA 4X 316 stainless steel corrosion resistance).

### SUMMARY

In one embodiment, an elastomeric gasket provided that is configured to be installed between a door and a safety switch housing. The gasket includes a super repellant coating.

In one embodiment, an apparatus is provided that includes an enclosure and a super repellant coated gasket. The enclosure is configured to house a safety switch and includes a housing having a cutout. The cutout is configured to be covered by an access panel. A gasket is placed between the housing and the access panel. The gasket is coated with a super repellant coating.

In one embodiment, the gasket is secured to the portion of the housing covered by the access panel. In another embodiment, the gasket is secured to the portion of the access panel that covers the portion of the housing. The super repellant coating may be a hydrophobic coating, a superhydrophobic coating, or an oleophobic coating. The gasket may be configured to be coated with the coating by at least one of painting, spraying rolling and dipping. The gasket may be constructed of at least one of aluminum, steel, ceramics, polymer, elastomer, wood, glass, and fabric. The gasket may have a flat profile in which one side of the flat profile includes a layer of adhesive. The gasket may be affixed to the apparatus by this layer of adhesive.

In one particular embodiment, the gasket is a single strip of elastomeric material that includes a slit traversing parallel to long edges of the strip and terminating in relief features proximate distal ends of the strip. The strip also includes pairs of opposing angled end features at distal ends of the strip. The pairs of angled end features are configured to abut one another to form corners of a rectangular shape. Opposing v-shaped notches extend from the slit and are configured to be collapsed to form corners of a rectangular shape.

### BRIEF DESCRIPTION OF THE DRAWINGS

The accompanying drawings, which are incorporated in and constitute a part of the specification, illustrate various example systems, methods, and other example embodiments of various aspects of the invention. It will be appreciated that the illustrated element boundaries (e.g., boxes, groups of boxes, or other shapes) in the figures represent one example of the boundaries. One of ordinary skill in the art will appreciate that in some examples one element may be designed as multiple elements or that multiple elements may be designed as one element. In some examples, an element shown as an internal component of another element may be implemented as an external component and vice versa. Furthermore, elements may not be drawn to scale.

FIG. 1 illustrates a front view of an example embodiment of safety switch enclosure with a coated gasket.

FIG. 2A illustrates a perspective view of an example embodiment of a coated gasket of FIG. 1.

FIG. 2B illustrates a cross-sectional view of the gasket of FIG. 2A.

FIG. 3 illustrates a diagram of the contact angle between a droplet of liquid and a coated gasket of FIG. 1.

### DETAILED DESCRIPTION

A safety switch includes one or more sets of electrical contacts that are housed in a protective enclosure. The electrical contacts are opened and closed with a lockable switch lever that is located outside the enclosure. In the food safety technologies, the electrical contacts are housed in an enclosure to isolate them from processing materials (e.g., food, byproducts, surfactants, disinfectants, moisture, and other contaminants). However, operators may need to periodically access the electrical contacts. Therefore, the enclosures are typically configured with an access panel such as a door. A gasket is positioned between the access panel and the door to seal the enclosure from contaminants.

Safety regulations for a food manufacturing plant may require that the equipment be disinfected regularly (e.g., every 28 days, daily, hourly) using disinfectant (e.g., surfactant, chlorine bleach). A typical NEMA 4/4X heavy duty stainless steel safety switch enclosure is exposed on a daily, or even hourly, basis to a wash of harsh chemicals including quaternary ammonia, acetates, degreasers, and other chemicals. In general, enclosures are 304 or 316 grade stainless steel to provide corrosion resistance against external contamination sources and harsh chemical cleaners. The gasket, which may be made from EPDM closed-foam rubber, is also exposed to the harsh contaminants, and breaks down over time due to chemical exposure in the processing environment. The intrusion and eventual external contamination of liquids into the safety switch leads to degradation of the electrical contacts. This is because the electrical contacts may begin to corrode to the point where they can no longer provide a closed electrical circuit.

According to the present invention, a gasket used to seal a safety switch enclosure is coated with a super repellant coating. The super repellant coating may be super hydrophobic, and/or oleophobic. Super repellant coatings cause liquids, such as water and oil, to bead up on the surface and exhibit a contact angle of at least 150 degrees and a roll-off angle of less than 10 degrees. In creating such a contact angle with the surface, the surface does not wet and is considered to be self-cleaning. This property is known as the Lotus effect.

The Lotus effect refers to the very high water repellency (superhydrophobicity) exhibited by leaves of a lotus flower. Dirt particles are picked up by water droplets due to a complex microscopic and nanoscopic architecture of the surface which minimizes adhesion. Due to their high surface tension, water droplets tend to minimize their surface trying to achieve a spherical shape. On contact with a surface, adhesion forces result in wetting of the surface. Either complete or incomplete wetting may occur depending on the structure of the surface and the fluid tension of the droplet. The cause of the self-cleaning property is the hydrophobic water-repellent double structure of the surface. This enables the contact area and the adhesion force between surface and droplet to be significantly reduced, resulting in a self-cleaning surface. Thus, dirt particles with an extremely reduced contact area are picked up by water droplets and are thus easily cleaned off the surface. If a water droplet rolls across such a contaminated surface the adhesion between the dirt particle, irrespective of its chemistry, and the droplet is higher than between the particle and the surface.

Super repellant coatings can be applied to a vast array of substrates that include aluminum, steel, PVC, ceramics, plastics, wood, cardboard, and fabrics. Super repellant coatings that are suited for application on safety switch enclosure gaskets include Ross Technology Corporation's solvent based I-Coat and water based NuO Coat.

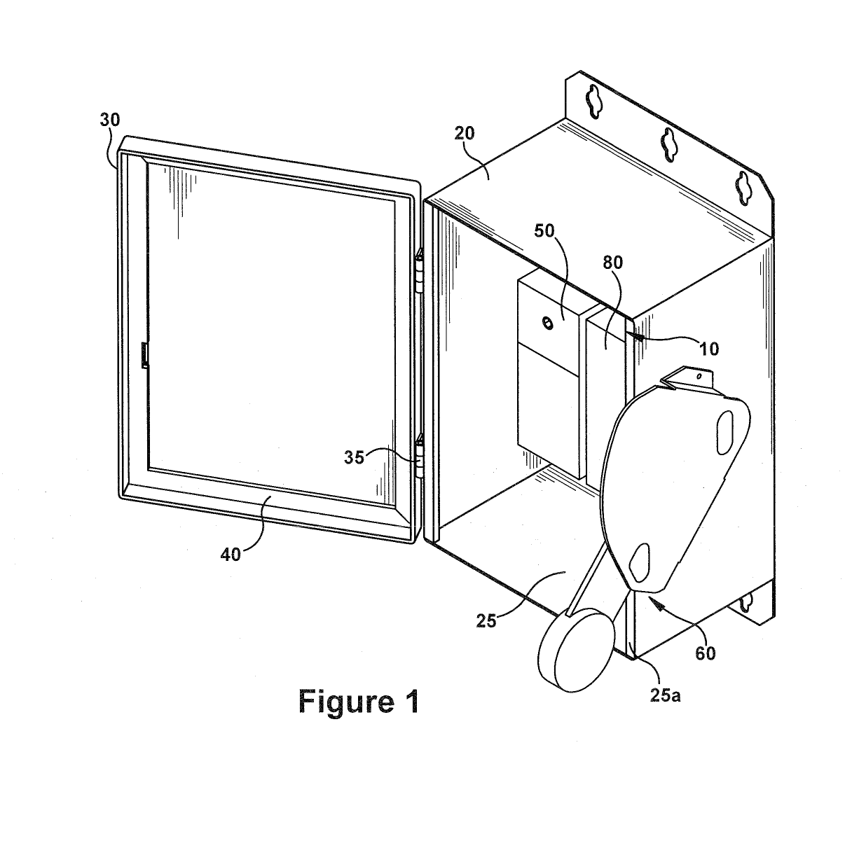

Referring to FIG. 1, an example embodiment of a safety switch enclosure 10 is illustrated. The enclosure 10 includes a housing 20 and a cutout, or front opening, 25 that provides access to the interior of the housing 20. To cover the front opening 25, the housing 20 includes an access panel, or door, 30 attached to the housing 20. The access panel 30 is configured to be larger than the front opening 25. Therefore, the access panel 30 covers the front opening 25 as well as portion of the housing 20. The access panel 30 may be attached to a face of the housing 20 with at least one access panel hinge 35 that allows the access panel 30 to pivot open in the manner of a door. The access panel 30 may be attached to the housing 20 at the side of the access panel 30. Alternatively, the access panel 30 may be attached to the housing 20 by the access panel hinge 35 at the top of the access panel 30. As an alternative to an access panel hinge 35, the access panel 30 may be secured to the housing 20 with fasteners (e.g., nails, screws, bolts, latches).

The safety switch includes a switch handle 60, a switching mechanism 80, and an electrical contactor set 50. The switching mechanism 80 and electrical contactor set 50 are located within the housing 20. The switch handle is located outside the housing 20 and is mechanically coupled to the switching mechanism through the wall of the enclosure 20. The switching mechanism 80 opens or closes the electrical contactor set 50 in response to rotation of the switch handle 60.

The electrical contactor set 50 is placed in the housing 20 to protect the electrical contactor set 50 from processing materials. The switch handle 60 may be rotated to open or close the electrical contactor set 50 without opening the access panel 30. The electrical contactor set 50 may be accessed through the front opening 25 when the access panel 30 is open. While one particular combination of a switch handle 60, switching mechanism 80, and electrical contactor set 50 is illustrated in FIG. 1, any number of combinations of handle types, switching mechanisms, and contactor sets may be enclosed by an enclosure that employs a super repellant coated gasket.

A coated gasket 40 is secured to the access panel 30. The coated gasket 40 may be made of a pliable material. The coated gasket 40 may be constructed of an elastomer (e.g., neoprene rubber, polyisoprene, polybutadiene, polyisobutylene, polyurethane). Alternatively, the coated gasket 40 may be constructed of one or a combination of aluminum, steel, ceramics, polymer, wood, glass, and fabrics. The coated gasket 40 may be flexible to allow the coated gasket 40 to form a seal. The coated gasket 40 is coated with a super repellent coating as will be described in more detail below.

The coated gasket 40 is placed on an interior surface of the access panel 30 so that it contacts an edge 25a of the housing 20 at the front opening 25. Alternatively, the coated gasket 40 may be affixed to the edge 25a of the housing. In either embodiment, when the access panel 30 covers the front opening 25, the housing 20 is separated from the access panel 30 by the coated gasket 40. The coated gasket 40 is compressed between the housing 20 and access panel 30 to form a seal. The coated gasket 40 may be compressed between the housing 20 and the access panel 30 with a compression mechanism (e.g. latch, screw, bolt, and so on).

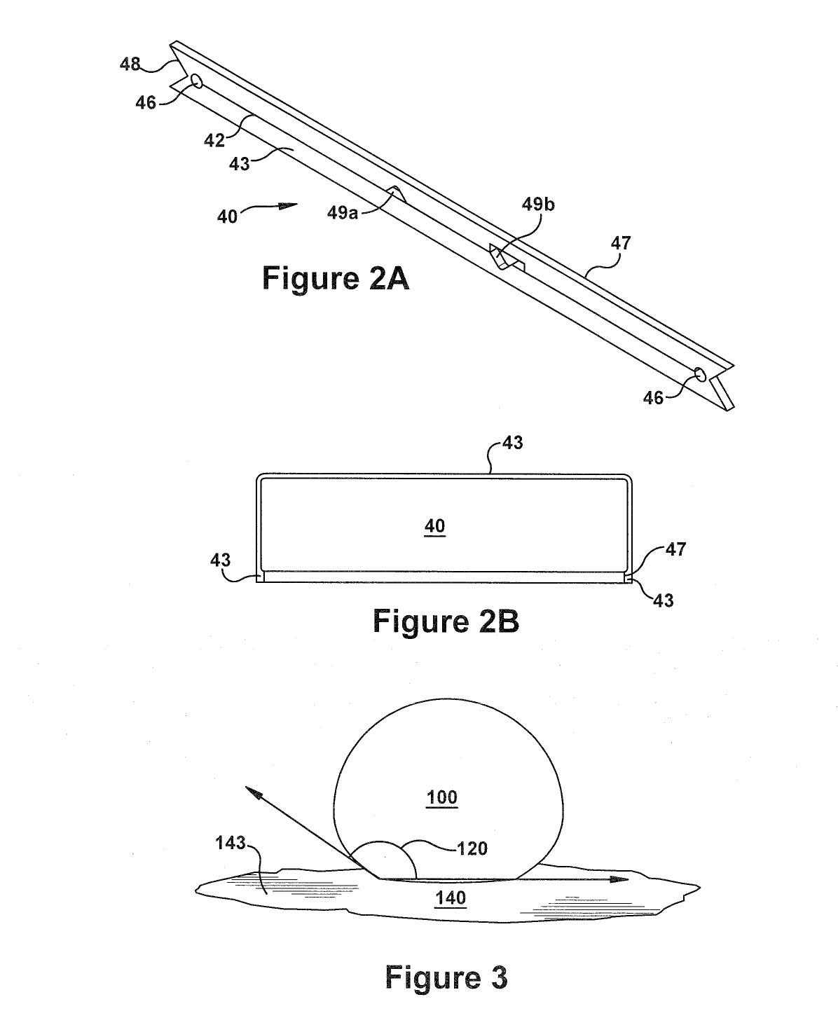

FIG. 2A is a perspective view of an example embodiment of the coated gasket 40. The coated gasket 40 is a single rectangular piece that is manipulated to form a rectangular gasket as shown installed in the access panel 30 in FIG. 1. The coated gasket 40 includes a slit 42 traversing between two relief holes 46 that prevent splitting when the gasket 40 is manipulated to form a rectangular shape. The coated gasket 40 includes opposing v-shaped notches 49a and 49b that are collapsed to form two corners of the rectangular gasket shape. Angled ends 48 form the other two corners of the rectangular gasket shape.

In other embodiments, the coated gasket 40 may be a composite structure consisting of individual pieces of coated gasket material. Strips of gasket material may be used to form the rectangular shape of the coated gasket 40. One of ordinary skill in the art will recognize that the coated gasket 40 can be formed as any shape (e.g., square, circle, ellipse, triangular, irregular). The shape of the coated gasket 40 may be formed as a single unit or formed as a composite structure.

One of ordinary skill in the art will recognize that the shape of the coated gasket 40 is based, at least in part, on the manner in which the coated gasket 40 is affixed to the electrical enclosure 10. The coated gasket 40 includes an adhesive backing 47 on a back surface by which the gasket may be affixed to the electrical enclosure 10. The adhesive backing may be pressure sensitive adhesive or cement. Alternatively, the coated gasket 40 may be affixed to the electrical enclosure 10 with a fastening mechanism (e.g., screws, nails, clamps, latches).

FIG. 2B illustrates a cross-sectional view of the coated gasket 40 of FIG. 2A. In the illustrated embodiment, the coated gasket 40 has a flat profile. The coated gasket 40 has a super repellent coating 43. The coating 43 reduces the likelihood of processing materials (e.g., food, byproducts, surfactants, disinfectants, moisture, contaminants) from entering the enclosure 10 (shown in FIG. 1) due to the anti-wicking properties of the coating 43. The super repellant coating 43 can be hydrophobic, superhydrophobic, or oleophobic.

In one embodiment the coating may be a solvent based coating. In another embodiment the coating may be water based coating. Both the solvent based and water based coatings contain nano particles that provide the super repellent properties dispersed in a micron particle binder material. The solvent based coating is formed by applying a top coat of nano particles after the binder micron particles have been applied to the gasket. This results in a thin layer of nano particles on top of the binder. The water based coating utilizes a polycarbonate and acrylic dispersion system in which the nano particles are evenly dispersed throughout the binder micron particles. Either of the coatings may be applied to the gasket by painting, spraying, rolling, or dipping.

One side of the profile of the coated gasket 40 includes an adhesive backing 47. The adhesive backing facilitates securing the coated gasket 40 to a component of an electrical enclosure 10 (shown in FIG. 1). The adhesive backing is installed on the gasket 40 prior to application of the coating 43. This allows for better adhesion of the adhesive backing 47 to the gasket material because the super repellant properties of the coating 43 would likely prevent secure installation of the adhesive backing.

FIG. 3 illustrates a diagram of the contact angle between a droplet of liquid 110 and a coated gasket 140. A super repellant coating 143 is layered on the coated gasket 140. The coating 143 may be hydrophobic, superhydrophobic, or oleophobic. The coating 143 is designed to repel liquid, such as water or oil. Accordingly, the droplet of liquid 110 beads up on the surface of the coated gasket 140. By beading up, the contact angle 120 between the coated gasket 140 and the droplet of liquid 110 is increased. For example, a droplet of liquid 110 may exhibit a contact angle 120 of 150° or greater with the coated gasket 140 and have a roll-off angle of less than 10°. The greater the contact angle 120 between the coated gasket 140 and the droplet of liquid 110, the more likely the droplet of liquid 110 is to roll off the coated gasket 140.

Due to the abusive conditions (high pressure sprays, high temperatures, surfactants, decontaminants, moisture) that the electrical enclosures are exposed to and the pliable structure of the gasket, the coatings for the gasket should be resistant to abrasion so that it is not washed away during extended use. Both solvent based (e.g., I Coat) and water based (e.g., NuO Coat) super repellant coatings initially provide a contact angle of greater than 150 degrees. In testing, a first set of gaskets were coated with the water based coating and a second set of gaskets were coated with the solvent based coating. Both sets of gaskets were then soaked for 13 hours in a cleaner concentration mixed with one part cleaner to one hundred parts water. There was no loss of surface functionality observed through the 13 hours of soaking for either the gaskets with water based coating or the gaskets with solvent based coating.

A number of tests were also run to determine whether a water based coating would be more abrasion resistant than a solvent based coating. It was hypothesized that the solvent based coating would outperform the water based coating because the water based coating would wear more than the solvent based coating. While the water based coating did exhibit more loss of material in abrasion testing, the water based coating better maintained its water repelling properties on metal substrates as well as exhibiting higher tensile strength than the solvent base coating when coating rubber substrates. This may be because the super repellant nano particles in the water based coating are dispersed below the surface while only the very top layer of the solvent based coating contains nano particles.

To the extent that the term “includes” or “including” is employed in the detailed description or the claims, it is intended to be inclusive in a manner similar to the term “comprising” as that term is interpreted when employed as a transitional word in a claim.

While example systems, methods, and so on have been illustrated by describing examples, and while the examples have been described in considerable detail, it is not the intention of the applicants to restrict or in any way limit the scope of the appended claims to such detail. It is, of course, not possible to describe every conceivable combination of components or methodologies for purposes of describing the systems, methods, and so on described herein. Therefore, the invention is not limited to the specific details, the representative apparatus, and illustrative examples shown and described. Thus, this application is intended to embrace alterations, modifications, and variations that fall within the scope of the appended claims.

What is claimed is:

1. An apparatus comprising:
an enclosure configured to house a safety switch, where the enclosure comprises a housing with a cutout, where the cutout is configured to be covered by an access panel;
a gasket placed between the housing and the access panel, where the gasket is coated with a super repellant coating.

2. The apparatus of claim 1, where the gasket is secured to the portion of the housing covered by the access panel.

3. The apparatus of claim 1, where the gasket is secured to the portion of the access panel that covers the portion of the housing.

4. The apparatus of claim 1, where the coating is a hydrophobic coating.

5. The apparatus of claim 1, where the coating is a superhydrophobic coating.

6. The apparatus of claim 1, where the coating is an oleophobic coating.

7. The apparatus of claim 1, where the gasket is configured to be coated with the coating by at least one of painting, spraying rolling and dipping.

8. The apparatus of claim 1, where the gasket is constructed of at least one of aluminum, steel, ceramics, polymer, elastomer, wood, glass, and fabrics.

9. The apparatus of claim 1, where the gasket has a flat profile, where one side of the flat profile comprises a layer of adhesive, and where the gasket is affixed to the apparatus by the layer of adhesive.

10. The apparatus of claim 1, where the gasket comprises a single strip of elastomeric material, comprising:
a slit traversing parallel to long edges of the strip and terminating in relief features proximate distal ends of the strip;
pairs of opposing angled end features at distal ends of the strip, the pairs of angled end features configured to abut one another to form corners of a rectangular shape; and
opposing v-shaped notches extending from the slit, the opposing v-shaped notches configured to be collapsed to form corners of a rectangular shape.

11. An apparatus comprising:
an elastomeric gasket configured to be installed between a door and a housing; and
a super repellant coating that coats at least a portion of the elastomeric gasket.

12. The apparatus of claim 11, where the elastomeric gasket is shaped to a boundary between the door and the housing.

13. The apparatus of claim 11, where the elastomeric gasket comprises a single strip of elastomeric comprising;
a slit traversing parallel to long edges of the strip and terminating in relief features proximate distal ends of the strip;
pairs of opposing angled end features at distal ends of the strip, the pairs of angled end features configured to abut one another to form corners of a rectangular shape; and
opposing v-shaped notches extending from the slit, the opposing v-shaped notches configured to be collapsed to form corners of a rectangular shape.

14. The apparatus of claim 11, where the super repellant coating is a hydrophobic coating.

15. The apparatus of claim 11, where the super repellant coating is a superhydrophobic coating.

16. The apparatus of claim 11, where the super repellant coating is an oleophobic coating.

17. The apparatus of claim 11, where the elastomeric gasket is configured to be coated with the super repellant coating by at least one of painting, spraying rolling and dipping.

18. The apparatus of claim 11, where the elastomeric gasket is constructed of at least one of neoprene rubber, polyisoprene, polybutadiene, polyisobutylene, and polyurethane.

19. The apparatus of claim 11, where the elastomeric gasket is a composite structure.

20. The apparatus of claim 11, where the composite structure is formed by a plurality of elastomeric gasket pieces.
